(19) United States
(12) Patent Application Publication
(10) Pub. No.: US 2026/0344075 A1
(43) Pub. Date: Oct. 29, 2026

(54) Image Sensor Having Glue Cavity

(71) Applicant: OmniVision Technologies, Inc., Santa Clara, CA (US)

(72) Inventors: Xiaowei Wang, San Jose, CA (US); Yin Qian, Milpitas, CA (US); Zhiqiang Lin, Fremont, CA (US); Lindsay Grant, Campbell, CA (US)

(21) Appl. No.: 19/468,973

(22) Filed: Feb. 3, 2026

Related U.S. Application Data
(63) Continuation of application No. 18/171,805, filed on Feb. 21, 2023, now abandoned.

(51) Int. Cl. H10F 39/00

(52) U.S. Cl. CPC H10F 39/804; H10F 39/805; H10F 39/8063

(57) ABSTRACT

An image sensor comprises an image sensor chip comprising a semiconductor substrate having a top surface and a plurality of microlenses disposed on the top surface; a cover glass having a first side in contact with air and a second side opposite to the first side; and a multi-layer structure disposed between the plurality of microlenses and the cover glass, which comprises: a bottom layer directly in contact with the plurality of microlenses, where the refractive index of the bottom layer is lower than the refractive index of the plurality of microlenses, and a top layer directly in contact with the second side of the cover glass, where the top layer is an optical glue made for bonding two optical elements.

### CROSS-REFERENCE TO RELATED APPLICATIONS

This application is a continuation of U.S. patent application Ser. No. 18/171,805 filed Feb. 21, 2023, the entire content of which is incorporated herein by reference.

### FIELD OF THE INVENTION

This invention relates to an image sensor having glue cavity, and more specifically relates to an image sensor having optical glue and low refractive index layer between microlenses of image sensor chip and cover glass.

### BACKGROUND OF THE INVENTION

An image sensor uses opto-electronic components, such as photodiodes, to detect incoming light and produce electronic signals in response. A primary component of the image sensor is its sensor pixel array, wherein each pixel includes a photodiode to convert photons to charge carriers, a floating node to temporarily store the charge carries, and a number of transistor gates (transfer gate, source follower, reset transistor, etc.) to convey the charge carriers out of the pixel to be further processed by a peripheral circuitry. An image sensor is often packaged with its supporting elements, which is then incorporated into an imaging product such as a mobile phone camera, a consumer electronic camera, a surveillance video camera, an automotive driver assistance device, a medical imaging endoscope, etc.

For the conventional chip scale package (CSP) of an image sensor, the cover glass is supported by dams which comprise insulation materials and adhesion materials, and are located on the periphery regions of an image sensor chip. The image sensor chip is the active part that detects light and converts it to electronic signal, which is cut from a wafer. When the image sensor continues scaled down, there is less and less periphery area for dams to land on. Such small periphery area will limit the dam width and consequently cause CSP reliability issue. Accordingly, new solutions for CSP without dam are demanded.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 illustrates an image sensor having chip scale package (CSP) with air cavity.

FIG. 2A illustrates partially an image sensor having CSP without air cavity.

FIG. 2B illustrates partially an image sensor having CSP with glue cavity.

FIG. 3A illustrates partially an image sensor having CSP with glue cavity, in accordance with the present invention.

FIG. 3B illustrates an embodiment of an image sensor having CSP with glue cavity, in accordance with the present invention.

FIG. 4 shows an analysis of light path in image sensor, in accordance with the present invention.

FIG. 5A illustrates a light pattern formed by reflected incidence light detected by image sensor chip, in accordance with the present invention.

FIG. 5B illustrates an image detected by image sensor chip, in accordance with the preset invention.

FIG. 6 illustrates partially an image sensor having CSP with glue cavity, in accordance with the present invention.

FIG. 7 shows an analysis of light path in image sensor, in accordance with the present invention.

FIG. 8A illustrates a light pattern formed by reflected incidence light detected by image sensor chip, in accordance with the present invention.

FIG. 8B illustrates an image detected by image sensor chip, in accordance with the present invention.

FIG. 9 illustrates partially an image sensor having CSP with glue cavity, in accordance with the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

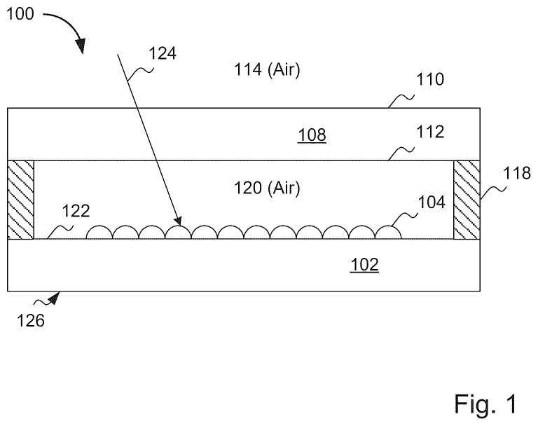

FIG. 1 illustrates an image sensor 100 having chip scale package (CSP) with air cavity. Image sensor 100 includes an image sensor chip 126 comprising a semiconductor substrate 102 having a top surface 122 to receive incident light 124, and a plurality of microlenses 104 disposed on top surface 122. Image sensor chip 126 may also comprise color filters, photodiodes, and others, not shown in the drawing. A dam 118 is disposed on top surface 122 surrounding microlenses 104. A cover glass 108 is disposed on dam 118. Cover glass 108 has a first side 110 and a second side 112, opposite to first side 110. First side 110 is in contact with air 114 outside image sensor 100. Dam 118 supports second side 112 of cover glass 108 with or without additional glue. A cavity with air 120 is enclosed by semiconductor substrate 102 and microlenses 104, cover glass 108, and surrounding dam 118.

Microlenses 104 interfaces with air 120 in the air cavity. The lensing effect of microlenses 104 is maximized because the refractive index difference between microlenses 104 and air 120 is maximum. The refractive index of air 120 is unity, which is the lowest possible refractive index. This results in highest energy collected by microlenses 104 by focusing incident light 124. Thus, the quantum efficiency of image sensor is high. However, dam 118 would take space of top surface 122 of semiconductor substrate 102. It would become a problem for image sensor scale down. It is appreciated that FIG. 1 is for illustration only and not to scale.

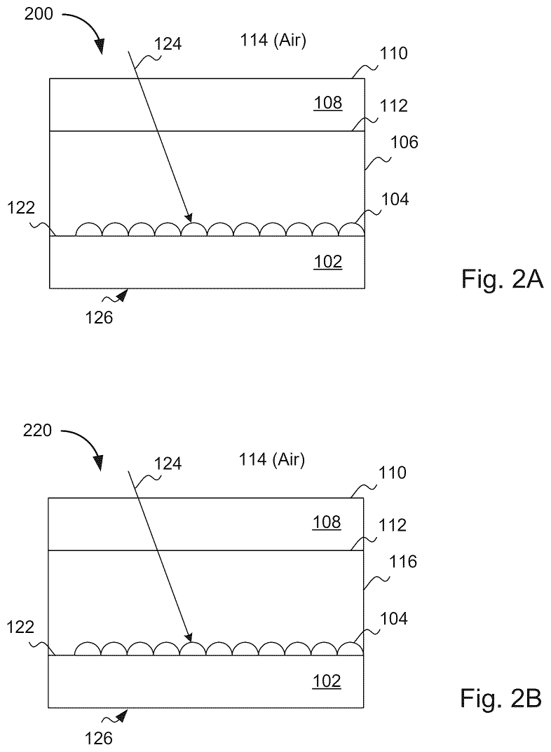

FIG. 2A illustrates partially an image sensor 200 having chip scale package (CSP) without air cavity. Image sensor 200 includes an image sensor chip 126 comprising a semiconductor substrate 102 having a top surface 122 to receive incident light 124, and a plurality of microlenses 104 disposed on top surface 122. Image sensor chip 126 also comprises color filters, photodiodes, and others, not shown in the drawing. A low refractive index (low-n) layer 106 is disposed on microlenses 104 and/or top surface 122 of semiconductor substrate 102. Low-n layer 106 is in contact with and covering microlenses 104. A cover glass 108 is disposed on low-n layer 106. Cover glass 108 has a first side 110 and a second side 112, opposite to first side 110. First side 110 is in contact with air 114 outside image sensor 200. Second side 112 is in contact with low-n layer 106. There is no air between microlenses 104 and cover glass 108.

Microlenses 104 interfaces with low-n layer 106. The lensing effect of microlenses 104 is in good order when refractive index difference between microlenses 104 and low-n layer 106 is large. In this case, although the refractive index of low-n layer 106 is higher than the refractive index of air, which is the lowest possible refractive index, good lensing effect may be achieved. For example, the refractive index of microlenses 104 may be 1.56, and the refractive index of low-n layer may be 1.21, this is sufficient to result in high energy collected by microlenses 104 by focusing incident light 124. The refractive index of low-n layer may be less than 1.3 or any number between 1.22 and 1.3. Thus, the quantum efficiency of image sensor 200 is still high.

FIG. 2B illustrates partially an image sensor 220 having a chip scale package (CSP) with glue cavity. FIG. 2B is similar to FIG. 2A, except an optical glue 116 replaces low-n layer 106. A reason of replacing low-n layer 106 with optical glue 116 because optical glue 116, which is made and/or used for bonding two optical elements, provides stronger bonding with cover glass 108 than that is provided by low-n layer 106. Thus, optical glue 116 brings a benefit of better reliability performance.

However, optical glue 116 has a typical refractive index around 1.5, for example 1.52, which is close to the refractive index of microlenses 104, for example, 1.56. This will weaken the lensing effect of microlenses 104, so less energy can be collected by microlenses 104 by focusing incident light 124. Thus, the quantum efficiency of image sensor 220 may be low. As an extreme example, when the refractive index of optical glue 116 is same as that of microlenses 104, incident light 124 may pass through microlenses 104 from optical glue 116 unaffected.

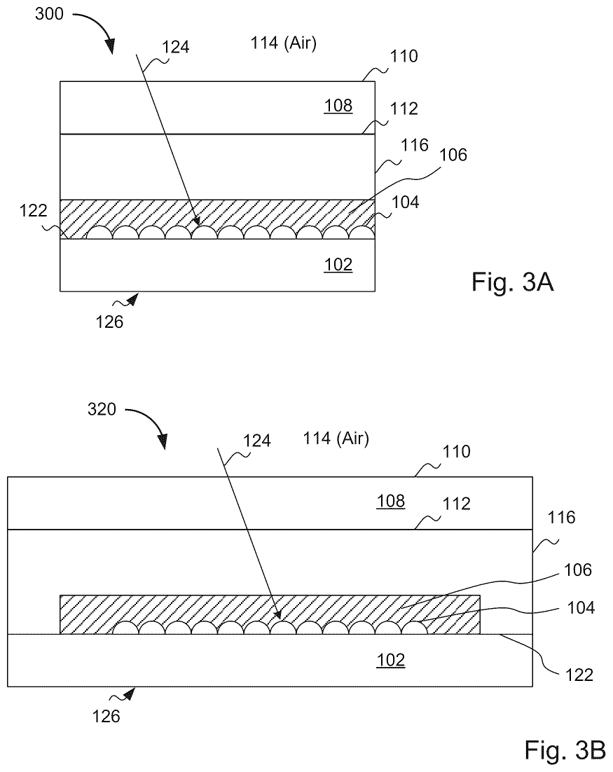

FIG. 3A illustrates partially an image sensor 300 having chip scale package (CSP) with glue cavity, in accordance with the present invention. FIG. 3A is also similar to FIG. 2A, except a combination of optical glue 116 and low-n layer 106 replacing single low-n layer 106. Although the cavity is filled with optical glue and low-n layer, for simplicity, this CSP may be referred as CSP with glue cavity. This configuration brings the benefit of high quantum efficiency when incident light 124 is focused by microlenses 104, and the benefit of better reliability performance because of stronger bonding between optical glue 116 and cover glass 108.

Following FIG. 3A, low-n layer 106 may be referred as a bottom layer of a multi-layer structure, which is directly in contact with and covering the plurality of microlenses 104. Optical glue 116 may be referred as a top layer of the multi-layer structure, which is directly in contact with the second side of cover glass 108. The multi-layer structure may be disposed between microlenses 104 and cover glass 108.

FIG. 3B illustrates an embodiment of an image sensor 320 having chip scale package (CSP) with glue cavity, in accordance with the present invention. Part of optical glue 116 may be disposed between cover glass 108 and semiconductor substrate 102. Part of optical glue 116 may fill the space between second side 112 of cover glass 108 and top surface 122 of semiconductor substrate 102 surrounding microlenses 104. Optical glue 116 may bond cover glass 108 and semiconductor substrate 102. Part of optical glue 116 may be disposed between cover glass 108 and low-n layer 106, which is disposed on microlenses 104. In another embodiment, for example shown in FIG. 3A, low-n layer 106 may cover microlenses 104 and an exposed part of top surface 122 of semiconductor substrate 102, and optical glue 116 may cover low-n layer 106.

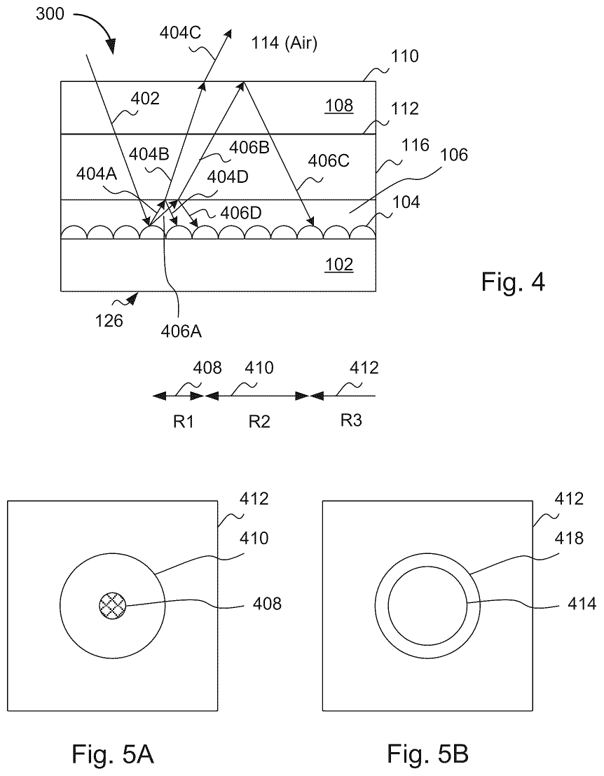

However, the configuration of FIG. 3A shows a drawback, which is the generation of a dark ring around a bright spot, as explained in FIG. 4. FIG. 4 shows an analysis of light path in image sensor 300, in accordance with the present invention. Light 402 is incident on microlenses 104. Light 402 may be incident light 124 in previous figures. The refraction of light 402 when it passes different layers to arrive at microlenses 104 is neglected, since it is not essential to the analysis here.

Light 402 may be reflected by microlenses 104 as light 406A in low-n layer 106. Light 406A is refracted as light 406B in optical glue 116. The refractive index of cover glass is typically 1.5. The refractive index of optical glue is typically around 1.5, for example 1.52. Since the refractive indices of optical glue 116 and cover glass 108 are close, almost no refraction and reflection occur at the interface of optical glue 116 and cover glass 108. For example, the refractive index of optical glue 116 and the refractive index of cover glass 108 have difference within 5% of the refractive index of cover glass 108. Light 406B passes the interface of optical glue 116 and cover glass 108, enters cover glass 108, and arrives at the interface of cover glass 108 and air 114 outside image sensor 300. The refractive index of cover glass 108 (n=1.5) is higher than air (n=1). For arriving light 406B having incidence angle larger than the critical angle, total reflection occurs at the interface of cover glass 108 and air 114 outside image sensor 300, light 406B will be total-reflected as light 406C. Reflected light 406C will be detected by image sensor chip 126 through microlenses 104.

Similarly, light 402 may be reflected by microlenses 104 as light 404A in low-n layer 106. Light 404A is refracted as light 404B in optical glue 116. Almost no refraction and reflection occur at the interface of optical glue 116 and cover glass 108. Light 404B passes the interface of optical glue 116 and cover glass 108, enters cover glass 108, and arrives at the interface of cover glass 108 and air 114 outside image sensor 300. For arriving light 404B having incidence angle smaller than the critical angle, no total reflection occurs at the interface of cover glass 108 and air 114 outside image sensor 300, light 404B will be mostly refracted as light 404C, leaving image sensor 300. Light 404C may not be detected by image sensor chip 126 through microlenses 104.

Light 406A and light 404A may be partially reflected at the interface of low-n layer 104 and optical glue 116 as light 406D and 404D, respectively. Light 406D and light 404D may be detected by image sensor chip 126 through microlenses 104. Light 406D and light 404D may be considered as the reflection of scattered light by microlenses 104.

Light 406D and light 404D may be detected in region R1 408. Light 406C from total reflection may be detected in region R3 412. Thus, region R1 408 and R3 412 may appear as background with low brightness or intensity. Light 404C leaving image sensor 300 is undetected by image sensor chip 126. Region R2 410 between regions R1 408 and R3 412, corresponds to undetected light 404C, which has much lower brightness or intensity than that of regions R1 408 and R3 412, or simply is a dark area.

For illustration, the thickness of low-n layer 104 may be about 1 μm or less than 2 μm, the thickness of optical glue 116 may be about 10 μm or less than 15 μm, and the thickness of cover glass 108 may be about 300 to 400 μm or less than 500 μm.

FIG. 5A illustrates a light pattern formed by reflected incidence light 402 detected by image sensor chip 126, in accordance with the present invention. Region R1 408 is low brightness area corresponding to reflected light 406D and 404D. Region R2 410 is a dark area corresponding to undetected light 404C. Region R3 412 is a low brightness area, may or may not be brighter than R1 408, corresponding to reflected light 406C of total reflection at the interface of cover glass 108 and air 114 outside image sensor 300.

FIG. 5B illustrates an image detected by image sensor chip 126, in accordance with the preset invention. The image is the superposition of the light pattern formed by reflected incidence light 402 shown in FIG. 5A, and a bright spot 414, which is the direct image of incidence light 402. The superposition results in a dark ring 418 surrounding bright spot 414. Dark ring 418 may not be desirable.

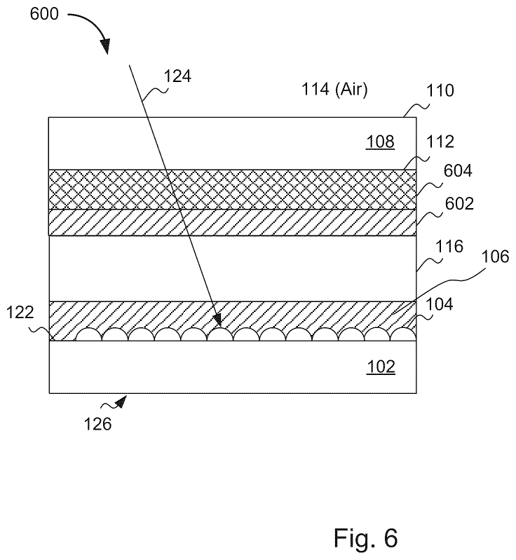

FIG. 6 illustrates partially an image sensor 600 having chip scale package (CSP) with glue cavity, in accordance with the present invention. Although the cavity is filled with the combination of optical glue and low-n layer, for simplicity, this CSP may be referred as CSP with glue cavity. Image sensor 600 includes an image sensor chip 126 comprising a semiconductor substrate 102 having a top surface 122 to receive incident light 124, and a plurality of microlenses 104 disposed on top surface 122. Image sensor chip 126 also comprises color filters, photodiodes, and others, not shown in the drawing. A first low refractive index (low-n) layer 106 is disposed on microlenses 104 and/or top surface 122 of semiconductor 102. First low-n layer 106 is in contact with and covering microlenses 104. A first optical glue 116 is disposed directly on first low-n layer 106. Optical glue is made and/or used for bonding two optical elements. A second low-n layer 602 is disposed directly on first optical glue 116. A second optical glue 604 is disposed directly on second low-n layer 602. A cover glass 108 is disposed on second optical glue 604. Cover glass 108 has a first side 110 and a second side 112, opposite to first side 110. First side 110 is in contact with air 114 outside image sensor 600. Second side 112 of cover glass 108 is in contact with second optical glue 604. There is no air between microlenses 104 and cover glass 108. First low-n layer 106 and second low-n layer 602 may be made of same material or different materials, and first optical glue 116 and second optical glue 604 may be made of same material or different materials.

Similar to FIG. 3A, the configuration of FIG. 6 brings the benefit of high quantum efficiency when incident light 124 is focused by microlenses 104, and the benefit of better reliability performance because of stronger bonding between second optical glue 604 and cover glass 108. Similar to FIG. 3B, second optical glue 604 may bond cover glass 108 and semiconductor substrate 102 (not shown in FIG. 6).

Following FIG. 6, first low-n layer 106 may be referred as a bottom layer of a multi-layer structure, which is directly in contact with and covering the plurality of microlenses 104. First optical glue 116 may be referred as first intermediate layer of the multi-layer structure. Second low-n layer 602 may be referred as second intermediate layer of the multi-layer structure. Second optical glue 604 may be referred as a top layer of the multi-layer structure, which is directly in contact with the second side of cover glass 108. The multi-layer structure may be disposed between microlenses 104 and cover glass 108.

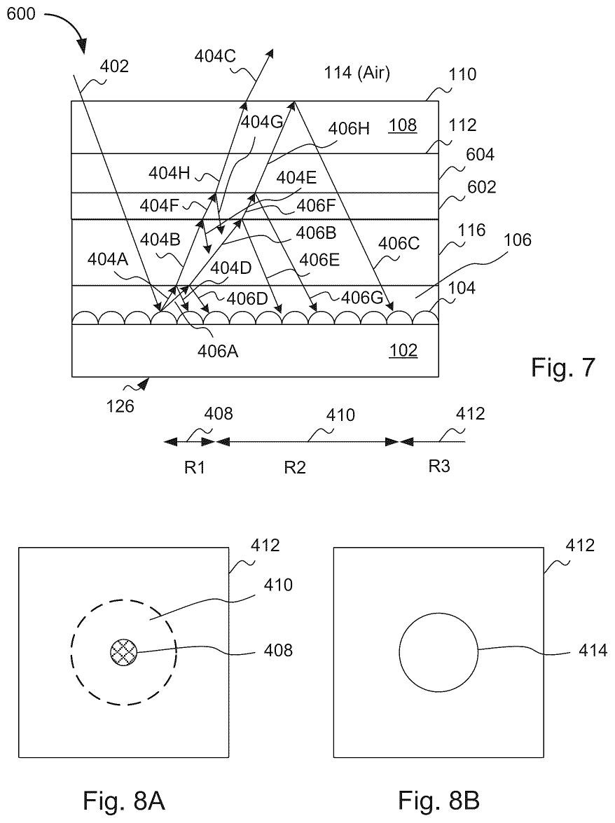

FIG. 7 shows an analysis of light path in image sensor 600, in accordance with the present invention. FIG. 7 is similar to FIG. 4. Light 402 is incident on microlenses 104. Light 402 may be incident light 124 in previous figures. The refraction of light 402 when it passes different layers to arrive at microlenses 104 is neglected, since it is not essential to the analysis here.

Light 402 may be reflected by microlenses 104 as light 406A in first low-n layer 106. Light 406A is partially refracted as light 406B in first optical glue 116. Light 406B is partially reflected at the interface of first optical glue 116 and second low-n layer 602 as light 406E. Light 406B is partially refracted as light 406F in second low-n layer 602. Light 406F is partially reflected at the interface of second low-n layer 602 and second optical glue 604 as light 406G. Light 406F is partially refracted as light 406H in second optical glue 604. Since the refractive indices of second optical glue 604 and cover glass 108 are close, almost no refraction and reflection occur at the interface of second optical glue 604 and cover glass 108. Light 406H passes the interface of second optical glue 604 and cover glass 108, enters cover glass 108, and arrives at the interface of cover glass 108 and air 114 outside image sensor 300. For arriving light 406H having incidence angle larger than the critical angle, total reflection occurs at the interface of cover glass 108 and air 114 outside image sensor 300, light 406H will be total-reflected as light 406C. Reflected light 406C will be detected by image sensor chip 126 through microlenses 104.

Similar to FIG. 4, light 402 may be reflected by microlenses 104 as light 404A in first low-n layer 106. Light 404A is partially refracted as light 404B in first optical glue 116. Light 404B is partially reflected at the interface of first optical glue 116 and second low-n layer 602 as light 404E. Light 404B is partially refracted as light 404F in second low-n layer 602. Light 404F is partially reflected at the interface of second low-n layer 602 and second optical glue 604 as light 404G. Light 404F is partially refracted as light 404H in second optical glue 604. Since the refractive indices of second optical glue 604 and cover glass 108 are close, almost no refraction and reflection occur at the interface of second optical glue 604 and cover glass 108. Light 404H passes the interface of second optical glue 604 and cover glass 108, enters cover glass 108, and arrives at the interface of cover glass 108 and air 114 outside image sensor 300. For arriving light 404H having incidence angle smaller than the critical angle of glass and air, no total reflection occurs at the interface of cover glass 108 and air 114 outside image sensor 600, light 404H will be mostly refracted as light 404C, leaving image sensor 600. Light 404C may not be detected by image sensor chip 126 through microlenses 104.

Light 406A and light 404A may be partially reflected at the interface of first low-n layer 104 and first optical glue 116 as light 406D and 404D, respectively. Partially reflected light 406D and light 404D, and partially reflected light 406E, 406G, 404E, and 404G may be detected by image sensor chip 126 through microlenses 104. The light detected may be considered as the reflection of scattered light by microlenses 104.

Light 406D and light 404D may be detected in region R1 408. Light 406C from total reflection at the interface of cover glass 108 and air 114 outside image sensor 600 may be detected in region R3 412. In contrast to FIG. 4, light 406E, 406G, 404E, and 404G may be detected in region R2 410. This will make all regions R1 408, R2 410, and R3 412 low brightness areas as background due to the reflection of scattered light by microlenses 104. No dark area appears.

For illustration, the thickness of first low-n layer 104 and/or second low-n layer 602 may be about 1 μm or less than 2 μm, the thickness of first optical glue 116 and/or second optical glue 604 may be about 10 μm or less than 15 μm, and the thickness of cover glass 108 may be about 300 to 400 μm or less than 500 μm.

FIG. 8A illustrates a light pattern formed by reflected incidence light 402 detected by image sensor chip 126, in accordance with the present invention. Regions R1 408, R2 410, and R3 412 may be all low brightness areas. Regions R1 408 and R2 410 may correspond to reflections from multiple interfaces, and region R3 may correspond to total internal reflection at the interface of cover glass 108 and air 114 outside image sensor 600. Although, regions R1 408, R2 410, and R3 412 may not have same brightness, but they all have no dark area. The dark area as shown in region R2 410 in FIG. 5A disappears.

FIG. 8B illustrates an image detected by image sensor chip 126, in accordance with the present invention. The image is the superposition of the light pattern formed by reflected incidence light 402 shown in FIG. 8A, and a bright spot 414, which is the direct image of incidence light 402. The superposition shows no dark ring (e.g., dark ring 418 in FIG. 5B) surrounding bright spot 414.

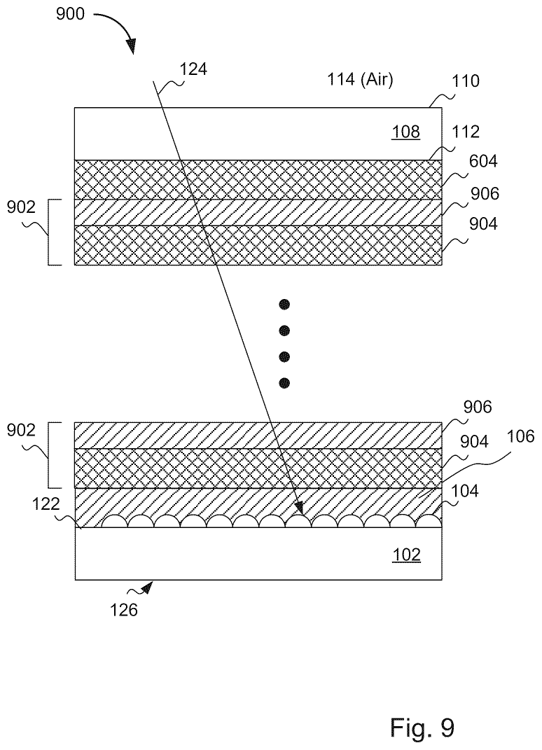

FIG. 9 illustrates partially an image sensor 900 having chip scale package (CSP) with glue cavity, in accordance with the present invention. Although the cavity is filled with the combination of optical glue and low-n layer, for simplicity, this CSP may be referred as CSP with glue cavity. FIG. 9 is similar to FIG. 6, except a plurality of layer-pairs 902 of a first layer 904 and a second layer 906 replacing first optical glue 116 and second low-n layer 602 between first low-n layer 106 and second optical glue 604. A first layer 904 of optical glue is disposed directly on first low-n layer 104. A second layer 906 of low-n is disposed directly on the first layer 904 of optical glue. Another first layer 904 of optical glue is disposed directly on the second layer 906 of low-n. Another second layer 906 of low-n is disposed directly on the other first layer 904 of optical glue. This structure may be repeated. Each first layer 904 and each second layer 906 form a layer-pair 902. First layer 904 has a refractive index higher than a refractive index of first low-n layer 104, second layer 906 has a refractive index lower than the refractive index of first layer 904. A first layer 904 of a layer-pair 902 is disposed directly on first low-n layer 104. A layer-pair is disposed directly on another layer-pair. Second optical glue 604 is disposed directly on a second layer 906 of a layer-pair 902.

First low-n layer 104 and second layer 906 of a layer-pair 902 may be made of same material or different materials, and second optical glue 604 and first layer 904 of a layer-pair 902 may be made of same material or different materials. First layer 904 of a layer pair and first layer 904 of another layer pair may be made of same material or different materials. Second layer 906 of a layer pair and second layer 906 of another layer pair may be made of same material or different materials. First layer 904 of a layer pair and first layer 904 of another layer pair may have same thickness or different thicknesses. Second layer 906 of a layer pair and second layer 906 of another layer pair may have same thickness or different thicknesses.

Similar to FIG. 6, the configuration of FIG. 9 brings the benefit of high quantum efficiency when incident light 124 is focused by microlenses 104, and the benefit of better reliability performance because of stronger bonding between second optical glue 604 and cover glass 108. Furthermore, no dark ring (e.g., dark ring 418 in FIG. 5B) will appear. Similar to FIG. 3B, second optical glue 604 may bond cover glass 108 and semiconductor substrate 102 (not shown in FIG. 9).

Following FIG. 9, first low-n layer 106 may be referred as a bottom layer of a multi-layer structure, which is directly in contact with and covering the plurality of microlenses 104. First layer 904 of a layer-pair 902 may be referred as a first layer of a layer-pair. Second layer 906 of a layer-pair 902 may be referred as a second layer of a layer-pair. Second optical glue 604 may be referred as a top layer of the multi-layer structure, which is directly in contact with the second side of cover glass 108. The multi-layer structure may be disposed between microlenses 104 and cover glass 108.

For illustration, the thickness of first low-n layer 104 and/or second layer 906 may be about 1 μm or less than 2 μm, the thickness of second optical glue 604 and/or first layer 904 may be about 10 μm or less than 15 μm, and the thickness of cover glass 108 may be about 300 to 400 μm or less than 500 μm.

By combining FIG. 3A, FIG. 6, and FIG. 9, an image sensor 300, 600, 900 comprises (1) an image sensor chip 126 comprising a semiconductor substrate 102 having a top surface 122 to receive light 124 and a plurality of microlenses 104 disposed on top surface 122; (2) a cover glass 108 having a first side 110 in contact with air 114 and a second side 112 opposite to first side 110; and (3) a multi-layer structure disposed between microlenses 104 and cover glass 108, which comprises: (a) a bottom layer 106 directly in contact with and covering microlenses 104, and where the refractive index of bottom layer 106 is lower than the refractive index of microlenses 104, and (b) a top layer 116, 604, directly in contact with second side 112 of cover glass 108, and where top layer 116, 604 is an optical glue made for bonding two optical elements.

While the present invention has been described herein with respect to the exemplary embodiments and the best mode for practicing the invention, it will be apparent to one of ordinary skill in the art that many modifications, improvements and sub-combinations of the various embodiments, adaptations, and variations can be made to the invention without departing from the spirit and scope thereof.

The terms used in the following claims should not be construed to limit the invention to the specific embodiments disclosed in the specification and the claims. Rather, the scope is to be determined entirely by the following claims, which are to be construed in accordance with established doctrines of claim interpretation. The present specification and figures are accordingly to be regarded as illustrative rather than restrictive.

What is claimed is:

1. An image sensor comprising:
an image sensor chip, wherein the image sensor chip comprises:
a semiconductor substrate having a top surface to receive light; and
a plurality of microlenses disposed on the top surface;
a cover glass having a first side in contact with air and a second side opposite to the first side; and
a multi-layer structure, disposed between the plurality of microlenses and the cover glass, and comprising::
a bottom layer directly in contact with and covering the plurality of microlenses, and wherein a refractive index of the bottom layer is lower than a refractive index of the plurality of microlenses; and
a top layer that is directly in contact with the second side of the cover glass and bonds the cover glass and the semiconductor substrate;
wherein part of the top layer fills a space between the second side of the cover glass and the top surface of the semiconductor substrate surrounding the plurality of microlenses.

2. The image sensor of claim 1, wherein the top layer is an optical glue made for bonding two optical elements.

3. The image sensor of claim 1, wherein a refractive index of the top layer and a refractive index of the cover glass being within 5% of the refractive index of the cover glass.

4. The image sensor of claim 1, wherein the refractive index of the bottom layer is less than 1.3.

5. The image sensor of claim 1, wherein the multi-layer structure has the bottom layer and the top layer only.

6. The image sensor of claim 1, wherein the multi-layer structure has a first intermediate layer disposed directly on the bottom layer and a refractive index of the first intermediate layer is higher than the refractive index of the bottom layer, and a second intermediate layer disposed directly on the first intermediate layer and a refractive index of the second intermediate layer is lower than the refractive index of the first intermediate layer, and wherein the top layer is disposed directly on the second intermediate layer.

7. The image sensor of claim 6, wherein the bottom layer and the second intermediate layer are made of same material, and the top layer and the first intermediate layer are made of same material.

8. The image sensor of claim 1, wherein the multi-layer structure has a plurality of layer-pairs of a first layer and a second layer between the bottom layer and the top layer, the first layer has a refractive index higher than a refractive index of the bottom layer, the second layer has a refractive index lower than the refractive index of the first layer, a first layer of a layer-pair is disposed directly on the bottom layer, a layer-pair is disposed directly on another layer-pair, and the top layer is disposed directly on a second layer of a layer-pair.

9. The image sensor of claim 1, wherein a thickness of the bottom layer is less than 2 μm.

10. The image sensor of claim 1, wherein a thickness of the top layer is less than 15 μm.

11. The image sensor of claim 1, wherein a thickness of the cover glass is less than 500 μm.

12. An image sensor comprising:
an image sensor chip, wherein the image sensor chip comprises:
a semiconductor substrate having a top surface to receive light; and
a plurality of microlenses disposed on the top surface;
a cover glass having a first side in contact with air and a second side opposite to the first side;
a bottom layer directly in contact with and covering the plurality of microlenses, wherein a refractive index of the bottom layer is lower than a refractive index of the plurality of microlenses;
a first intermediate layer disposed directly on the bottom layer, wherein a refractive index of the first intermediate layer is higher than the refractive index of the bottom layer;
a second intermediate layer disposed directly on the first intermediate layer, wherein a refractive index of the second intermediate layer is lower than the refractive index of the first intermediate layer; and
a top layer disposed directly on the second intermediate layer and directly in contact with the second side of the cover glass.

13. The image sensor of claim 12, wherein the top layer is an optical glue made for bonding two optical elements.

14. The image sensor of claim 12, wherein the refractive index of the bottom layer is less than 1.3.

15. An image sensor comprising:
an image sensor chip, wherein the image sensor chip comprises:
a semiconductor substrate having a top surface to receive light; and
a plurality of microlenses disposed on the top surface;
a cover glass having a first side in contact with air and a second side opposite to the first side; and
a multi-layer structure, disposed between the plurality of microlenses and the cover glass, and comprising:
a bottom layer directly in contact with and covering the plurality of microlenses, and wherein a refractive index of the bottom layer is lower than a refractive index of the plurality of microlenses;
a top layer directly in contact with the second side of the cover glass; and
plurality of layer-pairs of a first layer and a second layer between the bottom layer and the top layer, the first layer having a refractive index higher than a refractive index of the bottom layer, the second layer having a refractive index lower than the refractive index of the first layer, a first layer of a layer-pair being disposed directly on the bottom layer, a layer-pair being disposed directly on another layer-pair, and the top layer being disposed directly on a second layer of a layer-pair.

16. The image sensor of claim 15, wherein a first layer of a layer-pair and a first layer of another layer pair have different thicknesses.

17. The image sensor of claim 15, wherein a second layer of a layer-pair and a second layer of another layer pair have different thicknesses.

18. The image sensor of claim 15, wherein a first layer of a layer-pair and a first layer of another layer pair are made of different materials.

19. The image sensor of claim 15, wherein a second layer of a layer-pair and a second layer of another layer pair made of different materials.
